(19) United States
(12) Patent Application Publication
(10) Pub. No.: US 2010/0283068 A1
(43) Pub. Date: Nov. 11, 2010

(54) Colour Optoelectronic Device

(75) Inventors: Alastair Robert Buckley, Sheffield (GB); Christopher Yates, Edinburgh (GB)

Correspondence Address: HOWSON & HOWSON LLP, 501 OFFICE CENTER DRIVE, SUITE 210, FORT WASHINGTON, PA, 19034, US

(73) Assignee: MICROEMISSIVE DISPLAYS LIMITED, Edinburgh (GB)

(21) Appl. No.: 12/514,620

(22) PCT Filed: Nov. 16, 2007
(86) PCT No.: PCT/GB2007/004401

§ 371 Date: Jul. 2, 2010

(30) Foreign Application Priority Data
Nov. 17, 2006 (GB) 0622998.3

(51) Int. Cl. H01L 33/52

(52) U.S. Cl. 257/89; 257/E33.059

(57) ABSTRACT

An organic light emitting diode microdisplay device comprises a substrate including active circuitry (16) for addressing sub-pixels (10, 12, 14) of the device formed on the substrate, a metal anode layer (18), organic layers (22) at least including a light-emitting layer, a cathode layer (26) and encapsulation layers (28). The device includes at least one photonic lattice (24) having different, well-defined spacings for each sub-pixel that is arranged to emit light of a different colour. The device relies entirely on the photonic lattice (24) to determine the colour of light outcoupled from each sub-pixel.

### BACKGROUND TO THE INVENTION

This invention relates to a microdisplay comprising organic light emitting diode (OLED) pixels.

All LED devices suffer from the problem of light extraction. The root of the problem lies in traditional optics and the concept of total internal reflection. As all LED devices (OLED and inorganic LED) consist of stacks of thin films of high refractive index materials the chance of a photon escaping from the device is actually quite low and as such the external efficiency of the LED can be seriously limited. In traditional indicator LED's the problem is solved by capping the device with a hemispherical plastic shell to increase the number of angles capable of allowing light to pass. In OLED devices the solution is more complex as the LED device is typically required to be planar in its use as an information display.

It is widely known that light outcoupling of OLED devices can be controlled in terms of magnitude by the insertion of 1D or 2D grating structures, with spatial dimensions of the order of magnitude of the wavelength of visible light, either within the device structure or in close proximity to the device. The case of a 2D grating is known as a photonic lattice. It has been shown that the effect depends on wavelength to an extent (M. Kitamura, S. Iwamoto, Y. Arakawa, “Enhanced Luminance Efficiency of Organic Light-Emitting Diodes with Two-Dimensional Photonic Crystals”, Japanese Journal of Applied Physics, Vol. 44, No. 4B, 2005, pp. 2844-2848).

In a known OLED microdisplay light generation is already confined in 1D by the presence of a microcavity through the highly reflective anode metal (Al or Ti) and the partly reflective cathode layer. The finesse and thickness of this cavity controls the emission colour and magnitude of the outcoupling.

By introducing physical structures into the device with a length scale comparable with the wavelength of light that is required to be extracted, interference effects can increase or reduce the outcoupling of different wavelengths of light.

In a microcavity the interference effects are due to the confinement of light emission between two reflective, or semi reflective mirrors. In known devices manufactured by MicroEmissive Displays Limited the mirrors are actually the electrodes of the OLED device.

### SUMMARY OF THE INVENTION

The present invention take advantages of the photonic lattice structure. In a photonic lattice the interference effects are due to the creation a periodic physical structure where light of certain wavelengths is forbidden from propagating. To maximise the effect of the photonic crystal the periodic structure is ideally placed within the emitting region of the device.

In this invention photonic engineering is used to control the colour of the light emission in red, green and blue pixels.

By introducing a 2D photonic structure with different lattice spacing within each of the Red Green and Blue sub-pixels of the array, the magnitude and colour of the light emitted can be used to control the colour saturation of the display. In addition, as the forward emission of the pixel will be enhanced it will also be possible to reduce optical cross talk and as such enable smaller pixel sizes.

The invention provides an OLED microdisplay device according to claim 1. Optional features of the invention are set out in the dependent claims.

### BRIEF DESCRIPTION OF THE DRAWINGS

The invention will now be described in more detail, by way of example only, with reference to the accompanying drawings, in which:

FIGS. 1a to 1d schematically show photonic pixel lattice structures of different configurations;

FIGS. 2a to 2c schematically show photonic pixel lattice structures with different lattice spacings;

FIGS. 3a to 3c schematically show photonic pixel lattice structures of an alternative configuration with different lattice spacings;

FIG. 4 is a fragmentary sectional view of an OLED device according to an embodiment of the invention;

FIG. 5 is a spectrum of a known white OLED device;

FIG. 6 shows predicted outcouplings for optimal photonic pixels; and

FIGS. 7a to 7c show the outcouplings of FIG. 6 combined with the spectrum of FIG. 5.

### DETAILED DESCRIPTION OF PARTICULAR EMBODIMENTS

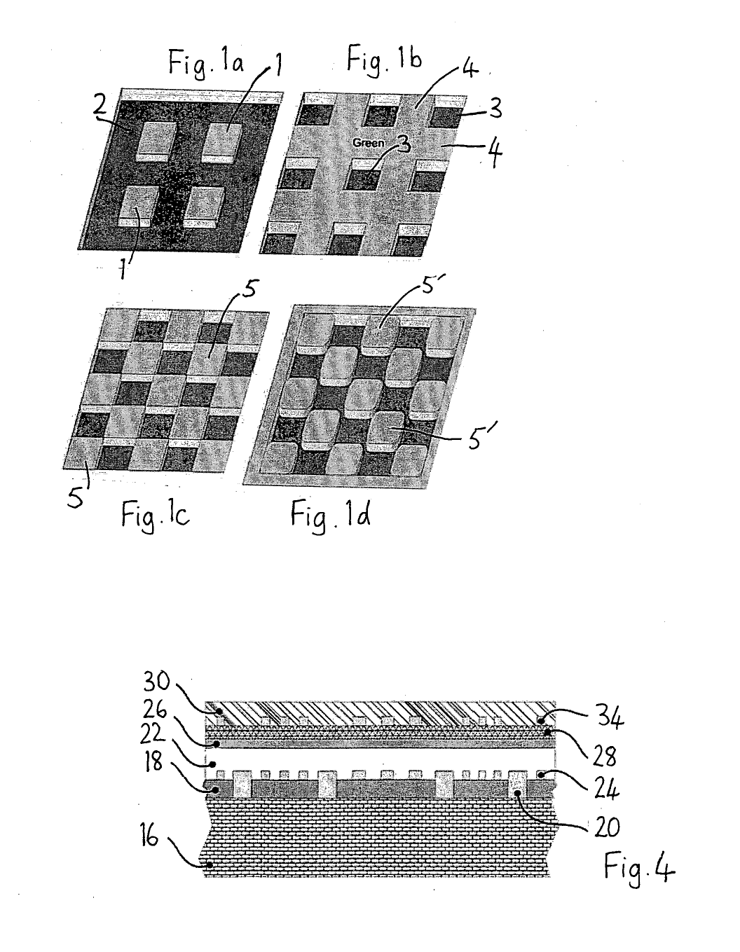

FIG. 1a shows a photonic lattice configured with pillars 1 of insulating material within an emissive area 2. FIG. 1b shows an alternative lattice with emitting sub-sub-pixels 3 confined with walls 4 of insulating material. FIG. 1c shows a lattice formed from a higher density matrix of pillars 5 and FIG. 1d shows a more realistic shape for the pillars 5′ fabricated by photolithography.

It is feasible to engineer such photonic lattice structures into a microdisplay device because semiconductor pattering technology, in particular CMOS technology, has the capability of patterning metal (typically aluminium) and insulator (silicon oxide or silicon nitride) to very high resolution (<0.5 μm).

Careful design of the spacing of a photonic lattice will provide enhanced out coupling of a certain wavelength of light. By engineering RGB sub-pixels to have difference and appropriate lattice spacing it is possible to enhance the outcoupling of a particular wavelength from each sub-pixel.

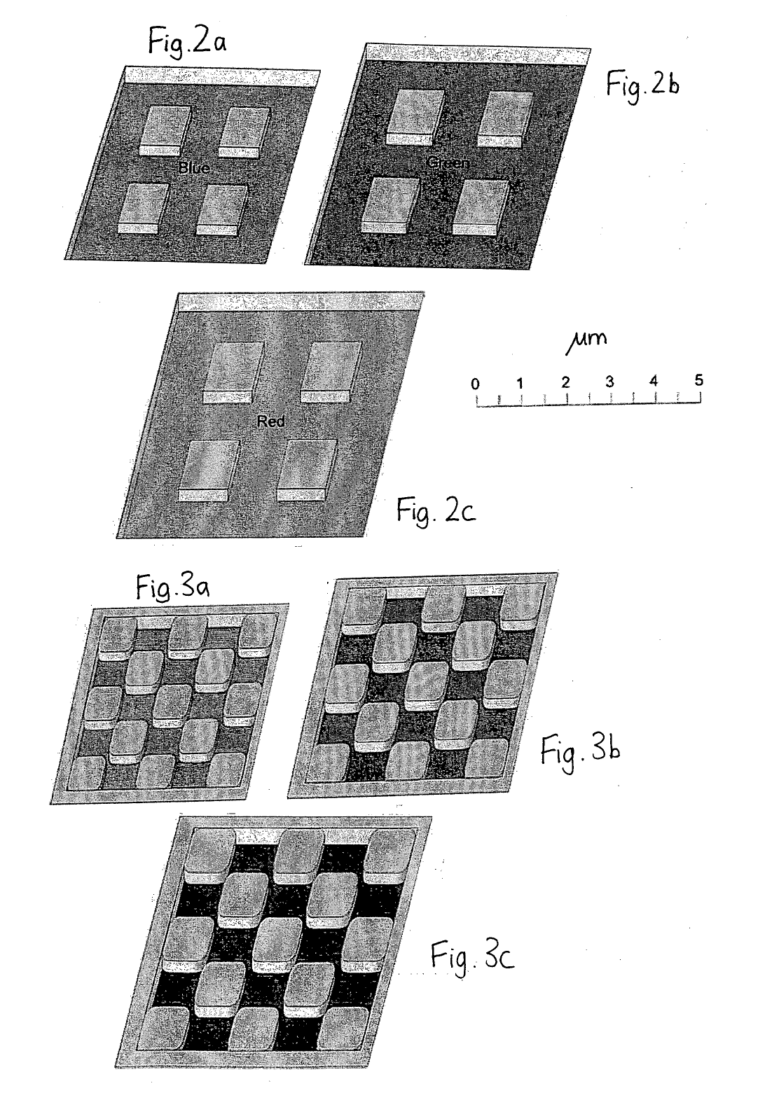

Thus FIGS. 2a to 2c show lattices based on FIG. 1a but with different lattice spacing such that in FIG. 2a blue light outcoupling is enhanced, in FIG. 2b green and in FIG. 2c red is enhanced.

Similarly, FIGS. 3a to 3c show lattices based on FIG. 1d but with different lattice spacing such that in FIG. 3a blue light outcoupling is enhanced, in FIG. 3b green and in FIG. 3c red is enhanced.

The photonic lattices enhance colour saturation of the display but also increase forward emission of each pixel.

FIG. 4 shows a device comprising a pixel formed from green, red and blue sub-pixels 10, 12, 14 respectively. The device comprises CMOS active circuitry 16 with a metal anode 18 formed thereon. Pixel walls 20 extend through the anode 18 into organic layers 22. These include hole and/or electron transport layers as well as a light-emitting layer. Photonic lattice elements 24 of well-defined lattice spacing and depth are formed on the anode 18 in the sub-pixel areas, for example from silicon oxide, silicon nitride or silicon oxynitride. The lattice spacings are optimal for the desired colour of light, as shown in FIGS. 2a to 2c and 3a to 3c. The device also comprises, in order, a metal cathode layer 26, encapsulation layers 28 and an adhesive 30. Photonic lattice elements 34 are also patterned on the encapsulation layers 28. It will be noted that the device of FIG. 4 requires no colour filters and relies entirely on the photonic lattices to determine the colour of light outcoupled from each sub-pixel.

An alternative device (not shown) has only one photonic lattice layer.

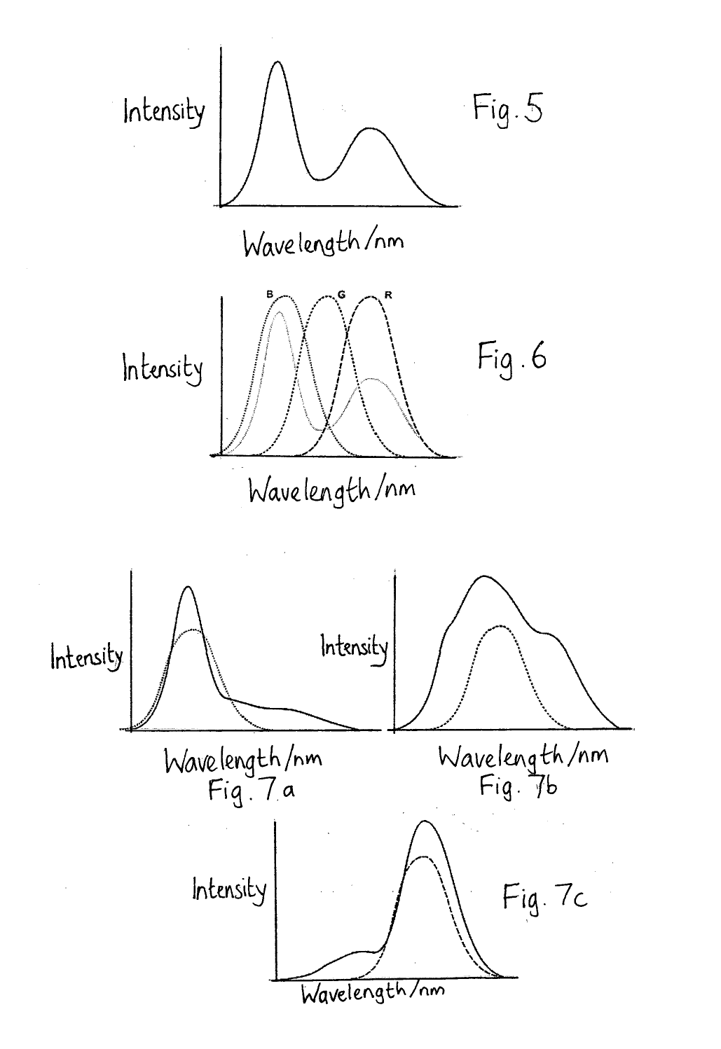

FIG. 5 shows the normalised electroluminescence spectrum of a known two-component white OLED.

FIG. 6 shows the predicted outcoupling functions from RGB pixels with photonic lattices according to the invention.

FIGS. 7a to 7c combine the spectra of FIGS. 5 and 6 for blue, green and red sub-pixels respectively and illustrate how the lattice may increase colour saturation in these RGB sub-pixels.

1. An organic light emitting diode microdisplay device comprising a substrate including active circuitry for addressing sub-pixels of the device formed on the substrate, a metal anode layer, organic layers at least including a light-emitting layer, a cathode layer and encapsulation layers, the device including at least one photonic lattice having different, well-defined spacings for each sub-pixel that is arranged to emit light of a different colour wherein the device relies entirely on the at least one photonic lattice to determine the colour of light outcoupled from each sub-pixel.

2. A device according to claim 1, wherein the photonic lattice or one of the photonic lattices is formed on the anode layer.

3. A device according to claim 2, wherein the photonic lattice or one of the photonic lattices is formed on an encapsulation layer of the device.

4. A device according to claim 3, wherein each photonic lattice is formed from at least one of silicon oxide, silicon nitride or silicon oxynitride.

5. A device according to claim 4, wherein the at least one photonic lattice consists of pillars of lattice material.

6. A device according to claim 5, wherein said pillars are arranged in a chequerboard configuration.

7. A device according to claim 4, wherein the at least one photonic lattice consists of intersecting walls of lattice material.

8. A device according to claim 2, wherein the at least one photonic lattice consists of intersecting walls of lattice material.

9. A device according to claim 1, wherein the photonic lattice or one of the photonic lattices is formed on an encapsulation layer of the device.

10. A device according to claim 9, wherein the at least one photonic lattice consists of intersecting walls of lattice material.

11. A device according to claim 9, wherein each photonic lattice is formed from at least one of silicon oxide, silicon nitride or silicon oxynitride.

12. A device according to claim 11, wherein the at least one photonic lattice consists of pillars of lattice material.

13. A device according to claim 12, wherein said pillars are arranged in a chequerboard configuration.

14. A device according to 1, wherein each photonic lattice is formed from at least one of silicon oxide, silicon nitride or silicon oxynitride.

15. A device according to claim 14, wherein the at least one photonic lattice consists of pillars of lattice material.

16. A device according to claim 15, wherein said pillars are arranged in a chequerboard configuration.

17. A device according to claim 14, wherein the at least one photonic lattice consists of intersecting walls of lattice material.

18. A device according to claim 1, wherein the at least one photonic lattice consists of pillars of lattice material.

19. A device according to claim 18, wherein said pillars are arranged in a chequerboard configuration.

20. A device according to claim 1, wherein the at least one photonic lattice consists of intersecting walls of lattice material.
